(19) United States
(12) Patent Application Publication
(10) Pub. No.: US 2025/0305120 A1
(43) Pub. Date: Oct. 2, 2025

(54) METHOD FOR SELECTIVE DEPOSITION OF LAYER OF INTEREST

(71) Applicant: Samsung Electronics Co., Ltd., Suwon-si (KR)

(72) Inventors: Geunho Choi, Suwon-si (KR); Eunhyea Ko, Suwon-si (KR); Gyuhee Park, Suwon-si (KR); Thanh Cuong Nguyen, Suwon-si (KR); Hiroyuki Uchiuzou, Tokyo (JP); Nana Okada, Tokyo (JP); Shuichi Masusaki, Wanju-gun (KR); Tomoharu Yoshino, Tokyo (JP); Yonggyun Kim, Wanju-gun (KR); Yoshiki Manabe, Wanju-gun (KR); Youn Joung Cho, Suwon-si (KR); Byungkeun Hwang, Suwon-si (KR)

(73) Assignees: Adeka Corporation, Tokyo (JP); Adeka Korea Corporation, Wanju-gun (KR)

(21) Appl. No.: 19/076,025

(22) Filed: Mar. 11, 2025

(30) Foreign Application Priority Data
Mar. 27, 2024 (KR) 10-2024-0042010
Sep. 27, 2024 (KR) 10-2024-0132008

(51) Int. Cl. C23C 16/40; C23C 16/04; C23C 16/455

(52) U.S. Cl. CPC C23C 16/40; C23C 16/042; C23C 16/45525

(57) ABSTRACT

Provided discloses an inhibitor capable of selectively adsorbing in a plurality of film environments and selectively depositing a subsequent film. Also provided are methods for selective deposition of a layer of interest with improved reliability by using an inhibitor having a superior selective deposition capability which can include forming of an inhibitor layer on a first surface wherein the inhibitor layer is chemically-adsorbed only to the first surface and is not adsorbed to a second surface.

### CROSS-REFERENCE TO RELATED APPLICATIONS

This application is based on and claims priority under 35 U.S.C. § 119 to Korean Patent Application No. 10-2024-0042010, filed on Mar. 27, 2024, and Korean Patent Application No. 10-2024-0132008, filed on Sep. 27, 2024, in the Korean Intellectual Property Office, the disclosures of which are incorporated by reference herein in their entirety.

### FIELD OF THE INVENTION

The inventive concept relates to a method for selective deposition of a layer of interest. More specifically, the inventive concept relates to a method of selectively depositing a film by using an inhibitor.

### BACKGROUND

With the development of electronic technologies, the down-scaling of semiconductor devices is rapidly progressing and thus patterns constituting electronic devices are becoming smaller. In line with this, the complexity of manufacturing processes of integrated circuit devices is increasing, and to implement such processes, there is a need for a technique for selective deposition of only some films formed of a specific material on a surface in which a plurality of films formed of different materials are exposed.

### SUMMARY

The inventive concept provides an inhibitor capable of selectively depositing a subsequent film through selective adsorption in a plurality of film environments.

The technical problems of the inventive concept are not limited to the technical problems mentioned above, and other technical problems not mentioned will be clearly understood by those of ordinary skill in the art from the description provided below.

To solve the technical problems, a selective deposition method for a layer of interest is provided.

According to an aspect of the inventive concept, there is provided a selective deposition method for a layer of interest, the selective deposition method comprising providing a first film comprising a first surface and a second film comprising a second surface, forming an inhibitor layer on the first surface of the first film, forming a layer of interest surrounding the second surface of the second film, and exposing the first surface by removing the inhibitor layer, in which the second film comprises at least one selected from among a low-k material, SiOx, an insulating material, a metal oxide, and a combination thereof, the inhibitor layer comprises an alkyl aldehyde, and the first film comprises at least one selected from among W, Mo, Ru, Cu, Co, and a combination thereof and at least one selected from among WOx, MoOx, RuOx, CuOx, CoOx, and a combination thereof.

According to another aspect of the inventive concept, there is provided a selective deposition method for a layer of interest, the selective deposition method comprising providing a first film comprising a first surface and a second film comprising a second surface, forming an inhibitor layer on the first surface of the first film, performing a vacuum break on the first film and the second film, forming a layer of interest surrounding the second surface of the second film, and exposing the first surface by removing the inhibitor layer, in which the second film comprises at least one selected from among a low-k material, SiOx, an insulating material, a metal oxide, and a combination thereof, the inhibitor layer comprises an aryl aldehyde, and the first film comprises at least one selected from among W, Mo, Ru, Cu, Co, and a combination thereof and at least one selected from among WOx, MoOx, RuOx, CuOx, CoOx, and a combination thereof.

According to another aspect of the inventive concept, there is provided a selective deposition method for a layer of interest, the selective deposition method comprising providing a first film comprising a first surface and a second film comprising a second surface, forming an inhibitor layer on the first surface of the first film, forming a layer of interest surrounding the second surface of the second film, and exposing the first surface by removing the inhibitor layer, in which the inhibitor layer comprises an aldehyde represented by:

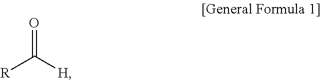

in which in General Formula 1, R indicates an alkyl group, an alkoxy group, an amine group (amide), a methoxy group (ester), an amide group (urea), or an ester group (acid anhydride), the first film comprises at least one selected from among W, Mo, Ru, Cu, Co, and a combination thereof and at least one selected from among WOx, MoOx, RuOx, CuOx, CoOx, and a combination thereof, and the second film comprises at least one selected from among a low-k material, SiOx, an insulating material, a metal oxide, and a combination thereof.

### BRIEF DESCRIPTION OF THE DRAWINGS

Embodiments of the inventive concept will be more clearly understood from the following detailed description taken in conjunction with the accompanying drawings in which:

FIG. 1 is a flowchart for describing a method for selective deposition of a layer of interest, according to embodiments;

FIGS. 2A to 2D are cross-sectional views for describing a method for selective deposition of a layer of interest, according to embodiments; and

FIGS. 3 to 7 are graphs showing experiment data according to an embodiment to illustrate a method for selective deposition of a layer of interest according to embodiments.

### DETAILED DESCRIPTION OF THE EMBODIMENTS

Hereinafter, embodiments will be described in detail with reference to the accompanying drawings. Like components in the drawings will be referred to as like reference numerals, and will not be repeatedly described.

The current embodiments may have various modifications thereto and various embodiments, and thus particular embodiments will be illustrated in the drawings and described in detail in a detailed description. It should be understood, however, that this is not intended to limit the inventive concept to a particular embodiment, and should be understood to include all changes, equivalents, and alternatives falling within the spirit and scope of the inventive concept. In describing an embodiment, when it is determined that the detailed description of the related art obscures the subject matter, a detailed description thereof will be omitted.

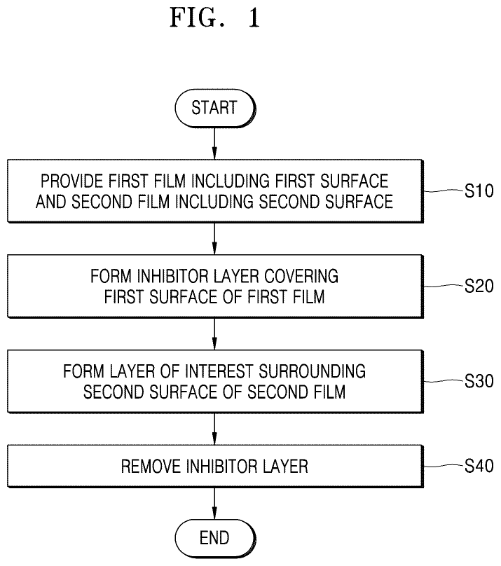

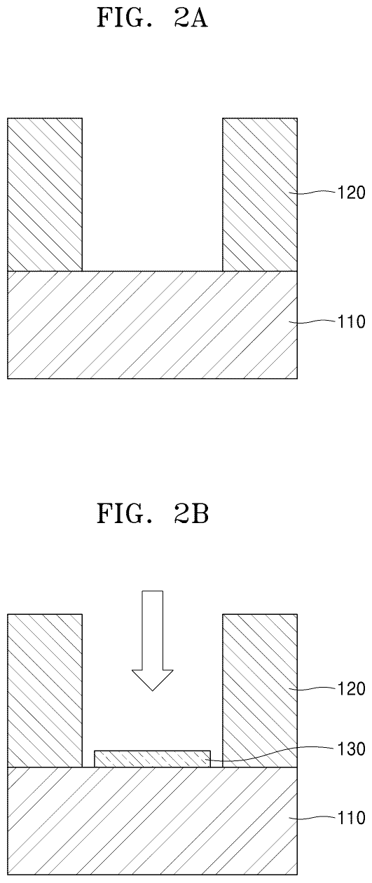

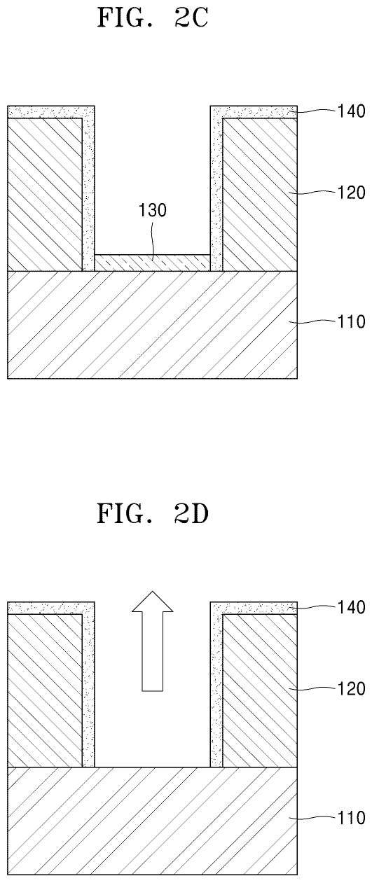

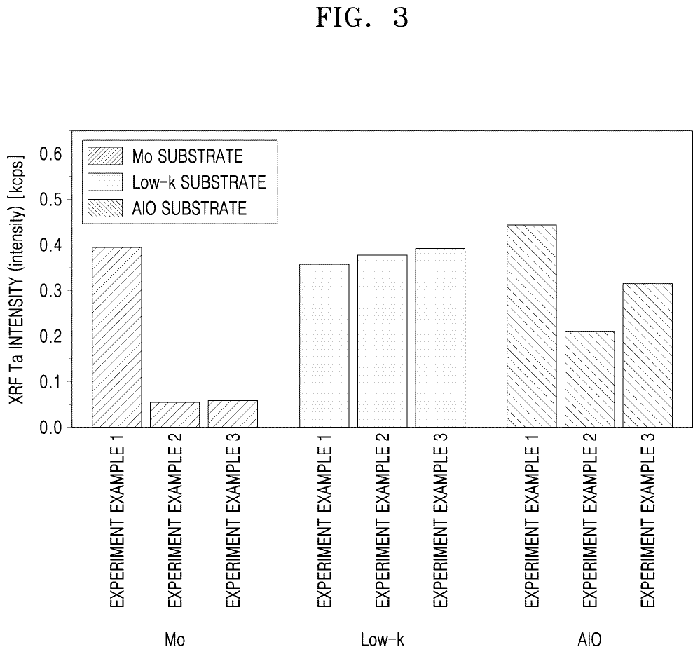

FIG. 1 is a flowchart for describing a method for selective deposition of a layer of interest, according to embodiments. FIGS. 2A to 2D are cross-sectional views for describing a method for selective deposition of a layer of interest, according to embodiments.

Referring to FIGS. 1 and 2A, a first film 110 and a second film 120 may be provided in operation S10.

The first film 110 may include metal. For example, the first film 110 may include various metal materials such as Cu, Mo, W, Ru, Co, some metal oxides, etc. Alternatively, the first film 110 may include at least one selected from WOx, MoOx, RuOx, CuOx, CoOx, and a combination thereof.

In some embodiments, the second film 120 may include an SiO film and a low-k material. For example, the second film 120 may include, but is not limited to, a tetraethylorthosilicate (TEOS) film, a high density plasma (HDP) oxide film, a boro-phospho-silicate glass (BPSG) film, a flowable chemical vapor deposition (FCVD) oxide film, an SiON film, an SiN film, an SiOC film, an SiCOH film, or a combination thereof.

In some embodiments, the second film 120 may be an oxide layer. For example, the second film 120 may include aluminum oxide, hafnium oxide, niobium oxide, silicon oxide, etc. However, the inventive concept is not limited thereto, and in some other embodiments, the second film 120 may include other oxides not described above as temperature and environment of an annealing process differ.

Referring to FIG. 2A, it is shown that the second film 120 is laminated on the first film 110 and a surface part of the first film 110 is exposed through a recess formed in the center of the second film 120, but this illustration is merely an example for helping understanding of the inventive concept and form, size, and mutual arrangement of the first film 110 and the second film 120 are not limited to the drawings.

For example, the first film 110 may be a composite film formed as a plurality of materials among materials of the first film 110 described as example form layers, respectively. For example, the second film 120 may be a composite film formed as a plurality of materials among materials of the second film 120 described as example form layers, respectively.

For example, the first film 110 and/or the second film 120 may have a plurality of steps.

Referring to FIGS. 1 and 2B, an inhibitor layer 130 covering an exposed first surface part of the first film 110 may be formed in operation S20.

The inhibitor layer 130 may be formed conformally on the first film 110, but the inventive concept is not limited thereto. A temperature for forming the inhibitor layer 130 and a time for forming the inhibitor layer 130 may vary depending on process condition and situation.

The inhibitor layer 130 may comprise an organic material including an aldehyde. The aldehyde that may be used as the inhibitor layer 130 may include an aryl group or an alkyl group.

That is, the aldehyde material may be used as a component part of the inhibitor layer 130 without significant restrictions on a functional group (R group). Examples of the functional group (R group) may include not only an alkyl group and an aryl group having 1 to 15 carbon atoms (e.g., 5 to 15carbon atoms or 10 to 15 carbon atoms), but also an alkoxy group, an amine group (amide), a methoxy group (ester), an amide group (urea), an ester group (acid anhydride), etc. However, the inventive concept is not limited thereto, and the number of carbon atoms may be 16 or greater.

In some embodiments, the inhibitor layer 130 may include an alkyl aldehyde. In some embodiments, the inhibitor layer 130 may include dodecanal. In some embodiments, the inhibitor layer 130 may include decanal.

In some embodiments, the inhibitor layer 130 may not be deposited on the second film 120. That is, the inhibitor layer 130 may not be formed on a silicon oxide and some metal oxides.

Referring to FIGS. 1 and 2C, a layer-of-interest 140 conformally surrounding a side surface and a top surface of the second film 120 may be formed, in operation S30. Next, referring to FIGS. 1 and 2D, the inhibitor layer 130 may be removed, such that the layer-of-interest 140 remaining on the second film 120 without being formed on the first film 110 may be obtained, in operation S40.

The layer-of-interest 140 may comprise, for example, a tantalum nitride. However, the inventive concept is not limited thereto, and the layer-of-interest 140 may comprise other materials without including tantalum.

The inhibitor may exist as a liquid at room temperature, and may comprise a material having high thermal stability. However, the inventive concept is not limited thereto, and the inhibitor may also exist as a solid at room temperature. The inhibitor layer 130 may be selectively adsorbed for various metal films. Thus, in a process of depositing the layer-of-interest 140, the layer-of-interest 140 may be inhibited from being formed on the metal film and thus may be deposited on the second film 120. As described above, when selective deposition of the layer-of-interest 140 is implemented, the layer-of-interest 140, which may have high resistivity, may not be on the first film 110 and thus a resistance of a metal contact may be reduced, reducing a via resistance.

A component material of the inhibitor layer 130 used in the inventive concept may perform a selective deposition function both in an in-situ process and an ex-situ process, as described below, thereby improving process flexibility.

The in-situ process refers to a process in which a process of forming a layer of interest after a process of forming an inhibitor layer may be performed without a vacuum break in one space (e.g., a chamber).

The ex-situ process refers to a process of forming the layer of interest with vacuum break after forming the inhibitor layer.

The vacuum break may refer to a process of returning to room temperature and normal pressure (760 torr) in an environment where a predetermined process pressure is maintained.

FIGS. 3 to 7 are graphs showing experiment data according to an embodiment to describe a method for selective deposition of a layer of interest according to embodiments. A description will be made with reference to FIGS. 3 to 7, together with Table 1 to Table 7.

In the following experiment examples, a Mo substrate, an AlO substrate, a low-k substrate, a W substrate, and a Cu substrate where a natural oxide film is formed are provided, and a pre-processing process made under the following conditions is carried out. The pre-processing process may be a process for removing the natural oxide film formed on the substrate and activating a surface.

### Condition

(1) Reaction Temperature: 250° C. to 400° C.

(2) Reaction Pressure: 107 Pa

(3) Reaction Time: 10 seconds

(4) Reaction Gas: H2 gas

(5) Reaction Gas Flow Rate: 100 ml/sec

(6) Plasma Output: 100 W

4-tert-butylbenzaldehyde (4TBBA) is provided as a first raw material used in the inhibitor, valeraldehyde is provided as a second raw material, octanal is provided as a third raw material, decanal is provided as a fourth raw material, and pentakis (dimethylamino) tantalum (V)(PDMAT) is provided as a raw material for forming a thin film. The inhibitor layer formed by the inhibitor may correspond to the inhibitor layer 130 described with reference to FIGS. 2A to 2D.

The first raw material is an aldehyde comprising an aryl group, and the second raw material, the third raw material, and the fourth raw material all are aldehydes comprising an alkyl group.

The first to fourth raw materials are provided, and by vaporization under the following conditions by using an atomic layer deposition (ALD) facility, an inhibitor is manufactured on a part of the substrate obtained by the pre-processing process, and a TaN film is formed using a raw material for forming a thin film, thereby obtaining a first substrate, a second substrate, a third substrate, and a fourth substrate. A fifth substrate is obtained by forming the TaN film using the raw material for forming a thin film. When a room temperature at which the first to fourth raw materials that are raw materials for inhibitors is applied is the same as the room temperature at the raw material for forming a thin film is applied, the method will be simply referred to as ‘single-temperature’, and when a room temperature at each step is different the method will be simply referred to as ‘multi-temperature’.

Hereinbelow, information about the first substrate, the second substrate, the third substrate, the fourth substrate, and the fifth substrate is provided.

### First Substrate

(1) Raw Material for Inhibitor: First Raw Material

(2) Reaction Temperature: 370° C.

(3) Reaction Pressure: 4000 Pa

(4) Reaction Time: 600 seconds

(5) Heating Temperature for Raw Material Container: 90° C.

(6) Internal Pressure for Raw Material Container: 1 kPa

(7) Carrier Gas: Ar

(8) Carrier Gas Flow Rate: 200 ml/sec

### Second Substrate

(1) Raw Material for Inhibitor: Second Raw Material

(2) Reaction Temperature: 250° C. to 400° C.

(3) Reaction Pressure: 4000 Pa

(4) Reaction Time: 600 seconds

(5) Heating Temperature for Raw Material Container: Room Temperature (25° C.)

(6) Internal Pressure for Raw Material Container: 1 kPa

(7) Carrier Gas: Ar

(8) Carrier Gas Flow Rate: 200 ml/sec

### Third Substrate

(1) Raw Material for Inhibitor: Third Raw Material

(2) Reaction Temperature: 400° C.

(3) Reaction Pressure: 4000 Pa

(4) Reaction Time: 600 seconds

(5) Heating Temperature for Raw Material Container: 60° C.

(6) Internal Pressure for Raw Material Container: 1 kPa

(7) Carrier Gas: Ar

(8) Carrier Gas Flow Rate: 200 ml/sec

### Fourth Substrate

(1) Raw Material for Inhibitor: Fourth Raw Material

(2) Reaction Temperature: 250° C. to 400° C.

(3) Reaction Pressure: 4000 Pa

(4) Reaction Time: 600 seconds

(5) Heating Temperature for Raw Material Container: 90° C.

(6) Internal Pressure for Raw Material Container: 1 kPa

(7) Carrier Gas: Ar

(8) Carrier Gas Flow Rate: 200 ml/sec

### Fifth Substrate

(1) Reaction Temperature: 250° C.

(2) Reaction Pressure: 107 Pa

(3) Raw Material Supply Time: 1 Second

(4) Heating Temperature for Raw Material Container: 80° C.

(5) Internal Pressure for Raw Material Container: 1 kPa

(6) Carrier Gas: Ar

(7) Carrier Gas Flow Rate: 200 ml/sec

(8) Reaction Gas: NH3

(9) Reaction Gas Flow Rate: 500 ml/sec

(10) Reaction Time: 1 Second

(11) Number of ALD Cycles: 33 cycles

FIG. 3 shows a graph of experiment data according to an embodiment to describe a method for selective deposition of a layer of interest according to embodiments.

The first substrate, the second substrate, and the fifth substrate obtained by experiment for forming an inhibitor and a thin-film forming film through vaporization are evaluated at multi-temperature and the effect of the inhibitor is checked. This result is described with reference to FIG. 3 and Table 1 together.

TABLE 1

| | | | Raw Material for | Strength for Forming | | |
|---|---|---|---|---|---|---|
| | | Raw Material for | Forming Thin | Thin Film (kcps) | | |
| | | Inhibitor | Film | | Low- | |
| | Substrate | Reaction Temperature | | Mo | k | AlxOy |
| Experiment | Fifth | — | 250° C. | 0.39 | 0.36 | 0.44 |
| Example 1 | Substrate | | | | | |
| Experiment | First | 370° C. | 250° C. | 0.06 | 0.37 | 0.21 |
| Example 2 | Substrate | | | | | |
| Experiment | Second | 370° C. | 250° C. | 0.06 | 0.39 | 0.31 |
| Example 3 | Substrate | | | | | |

Specifically, FIG. 3 is a graph for evaluating an inhibitory effect caused by an inhibitor through X-ray fluorescence analysis, and Table 1 shows detailed evaluation conditions of FIG. 3. Referring to FIG. 3, the effect of the inhibitor may be identified based on a spectral intensity caused by tantalum atoms on the substrate surface with or without the inhibitor.

Referring to FIG. 3 and Table 1, it may be seen that under the multi-temperature condition where the reaction temperature for the raw material for the inhibitor is 370° C., the inhibitor is selectively formed on the Mo substrate.

As the raw material for the inhibitor is effectively deposited on the substrate, X-ray fluorescence (XRF) Ta strength may be low. For the Mo substrate, the strength for forming a Ta thin film is measured as 0.39 kcps in Experiment Example 1 and the strength for forming a Ta thin film is measured as 0.06 kcps in Experiment Example 2 and Experiment Example 3, such that the raw material for the inhibitor is effectively deposited on the substrate. However, for the low-k substrate, the strengths for forming the Ta thin film in Experiment Example 1, Experiment Example 2, and Experiment Example 3 are respectively measured as 0.36 kcps, 0.37 kcps, and 0.39 kcps, and thus there is almost no difference between Experiment Examples and almost no inhibitor is deposited. For the AlO substrate, it may be seen that when an inhibitor is supplied at high temperature under the multi-temperature condition, a layer of interest is formed at a level (0.31 kcps) similar to the low-k substrate, and thus the inhibitor is not deposited.

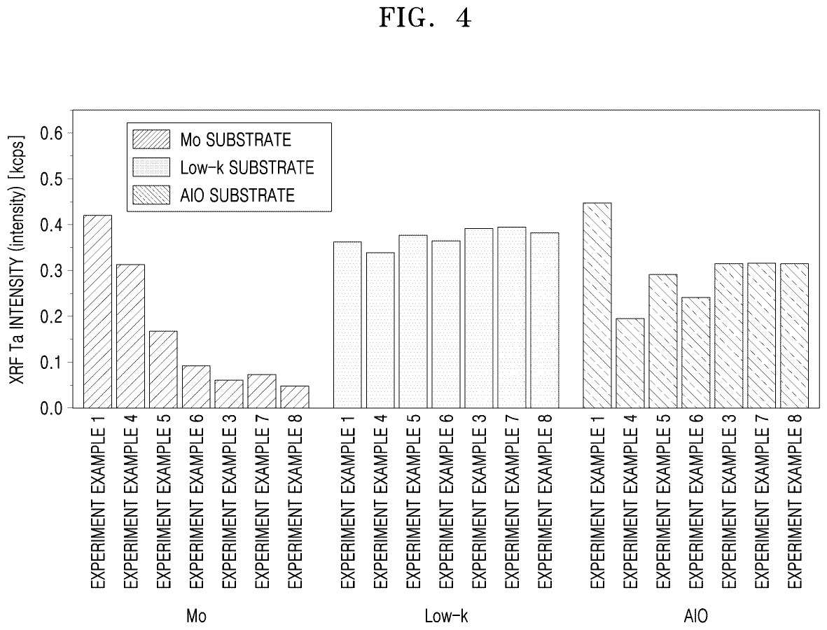

FIG. 4 shows a graph of experiment data according to an embodiment to describe a method for selective deposition of a layer of interest according to embodiments.

The second substrate and the fifth substrate obtained by experiment for forming an inhibitor and a thin-film forming film through vaporization are evaluated at single-temperature and multi-temperature and the effect of the inhibitor with respect to temperature is checked. This result is described with reference to FIG. 4 and Table 2 together.

TABLE 2

| | | | Raw Material | Strength for Forming | | |
|---|---|---|---|---|---|---|
| | | Raw Material for | for Forming | Thin Film (kcps) | | |
| | | Inhibitor | Thin Film | | Low- | |
| | Substrate | Reaction Temperature | | Mo | k | AlxOy |
| Experiment | Fifth | — | 250° C. | 0.42 | 0.36 | 0.44 |
| Example 1 | Substrate | | | | | |
| Experiment | Second | 250° C. | 250° C. | 0.31 | 0.34 | 0.20 |
| Example 4 | Substrate | | | | | |
| Experiment | Second | 330° C. | 250° C. | 0.17 | 0.38 | 0.29 |
| Example 5 | Substrate | | | | | |
| Experiment | Second | 350° C. | 250° C. | 0.09 | 0.36 | 0.24 |
| Example 6 | Substrate | | | | | |
| Experiment | Second | 370° C. | 250° C. | 0.06 | 0.39 | 0.31 |
| Example 3 | Substrate | | | | | |
| Experiment | Second | 385° C. | 250° C. | 0.07 | 0.40 | 0.32 |
| Example 7 | Substrate | | | | | |
| Experiment | Second | 400° C. | 250° C. | 0.05 | 0.17 | 0.31 |
| Example 8 | Substrate | | | | | |

Specifically, FIG. 4 is a graph for evaluating an inhibitory effect caused by an inhibitor through X-ray fluorescence analysis, and Table 2 shows detailed evaluation conditions of FIG. 4. Referring to FIG. 4, the effect of the inhibitor may be identified based on a spectral intensity caused by tantalum atoms with or without the inhibitor on the substrate surface.

Referring to FIG. 4 and Table 2, in a temperature range of 250°° C. to 400° C., the effect of inhibiting Ta thin film formation is exhibited. In comparison to the single-temperature condition, under the multi-temperature condition, as the Mo substrate reacts at high temperature, the effect of inhibiting Ta thin film formation increases, such that the inhibitory effect is saturated at 370° C. or higher. On the other hand, for the AlO substrate, as the AlO substrate reacts at high temperature, the effect of inhibiting Ta thin film formation is weakened and the inhibitory effect is saturated at 370°° C. or higher.

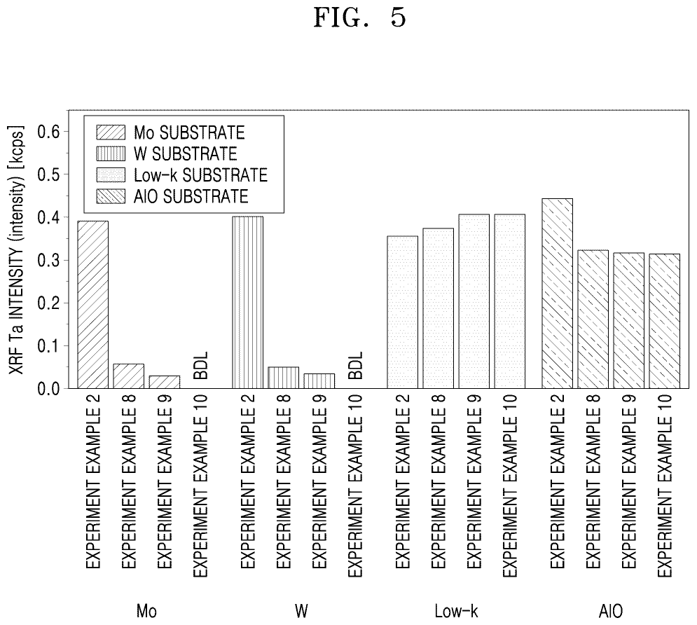

FIG. 5 shows a graph of experiment data according to an embodiment to illustrate a method for selective deposition of a layer of interest according to embodiments.

The second substrate, the third substrate, the fourth substrate, and the fifth substrate obtained by experiment for forming an inhibitor and a thin-film forming film through vaporization are evaluated at multi-temperature and the effect of the inhibitor for the W substrate is checked. This result is described with reference to FIG. 5 and Table 3 together.

TABLE 3

| | | | Raw | | | | |
|---|---|---|---|---|---|---|---|
| | | | Material for | | | | |
| | | Raw Material for | Forming | Strength for Forming | | | |
| | | Inhibitor | Thin Film | Thin Film (kcps) | | | |
| | Substrate | Reaction Temperature | | Mo | W | Low-k | AlxOy |
| Experiment | Fifth | — | 250° C. | 0.39 | 0.40 | 0.36 | 0.44 |
| Example 1 | Substrate | | | | | | |
| Experiment | Second | 400° C. | 250° C. | 0.05 | 0.05 | 0.17 | 0.31 |
| Example 8 | Substrate | | | | | | |
| Experiment | Third | 400° C. | 250° C. | 0.03 | 0.03 | 0.41 | 0.36 |
| Example 9 | Substrate | | | | | | |
| Experiment | Fourth | 400° C. | 250° C. | BDL | BDL | 0.41 | 0.31 |
| Example 10 | Substrate | | | | | | |

Specifically, FIG. 5 is a graph for evaluating an inhibitory effect caused by an inhibitor through X-ray fluorescence analysis, and Table 3 shows detailed evaluation conditions of FIG. 5. Referring to FIG. 5, the effect of the inhibitor may be identified based on a spectral intensity caused by tantalum atoms with or without the inhibitor on the substrate surface. BDL described in Table 3 refers to a below detection limit.

Referring to FIG. 5 and Table 3, even when any one of the second raw material (valeraldehyde), the third raw material (octanal), and the fourth raw material (decanal) is used as the raw material for the inhibitor, the effect of inhibiting Ta thin film formation is large for the Mo substrate and the W substrate. In addition, it may be seen that when the fourth raw material (decanal) is used, the effect of inhibiting Ta thin film formation is largest for the Mo substrate and the W substrate.

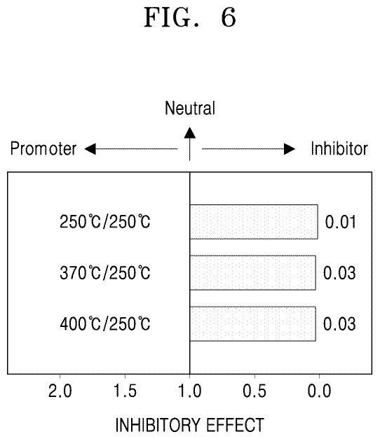

FIG. 6 shows a graph of experiment data according to an embodiment to illustrate a method for selective deposition of a layer of interest according to embodiments.

The fourth substrate obtained by experiment for forming an inhibitor and a thin-film forming film through vaporization is evaluated at multi-temperature and the effect of the inhibitor for the Cu substrate is checked. This result is described with reference to FIG. 6 and Table 4 together.

TABLE 4

| | | Raw | Raw | Spectrum Area of Normalized Thin Film | | |
|---|---|---|---|---|---|---|
| | | Material | Material | (arb. unit) | | |
| | | for | for Forming | Without Raw | With Raw | |
| | | Inhibitor | Thin Film | Material for | Material for | Effect |
| | Substrate | Reaction Temperature | | Inhibitor (1) | Inhibitor (2) | (2/1) |
| Experiment | Fifth | — | 250° C. | 0.31 | — | — |
| Example 1 | Substrate | | | | | |
| Experiment | Fourth | 250° C. | 250° C. | 0.31 | 0.002 | 0.01 |
| Example 11 | Substrate | | | | | |
| Experiment | Fourth | 370° C. | 250° C. | 0.31 | 0.008 | 0.03 |
| Example 12 | Substrate | | | | | |
| Experiment | Fourth | 400° C. | 250° C. | 0.31 | 0.008 | 0.03 |
| Example 13 | Substrate | | | | | |

Specifically, FIG. 6 is a graph for evaluating an inhibitory effect caused by an inhibitor through X-ray optoelectronic analysis, and Table 4 shows detailed evaluation conditions of FIG. 6. Referring to FIG. 6 and Table 4, the effect of inhibiting Ta thin film formation of the inhibitor may be identified by comparing spectral intensities caused by tantalum atoms with or without the inhibitor on the substrate surface.

Referring to FIG. 6 and Table 4, it may be seen that by using the fourth raw material (decanal), a large effect of inhibiting Ta thin film formation on the Cu substrate is obtained under the single-temperature condition and the multi-temperature condition.

That is, according to the foregoing description made with reference to FIGS. 3 to 6 and Table 1 to Table 4, in manufacturing of a semiconductor device according to the inventive concept, when the process described with reference to FIGS. 2A to 2D is performed (1) using an aldehyde compound (2) under the multi-temperature condition at 370° C. or higher, a large effect of inhibiting Ta thin film formation may be obtained for the Mo substrate and the W substrate. For the Cu substrate, when the process described with reference to FIGS. 2A to 2D is performed (1) using the fourth raw material (decanal) (2) under the single-temperature condition and the multi-temperature condition, a large effect of inhibiting Ta thin film formation may be obtained. For the AlO substrate, when the process described with reference to FIGS. 2A to 2D is performed under the multi-temperature condition, a high selectivity of the inhibitor may be expected.

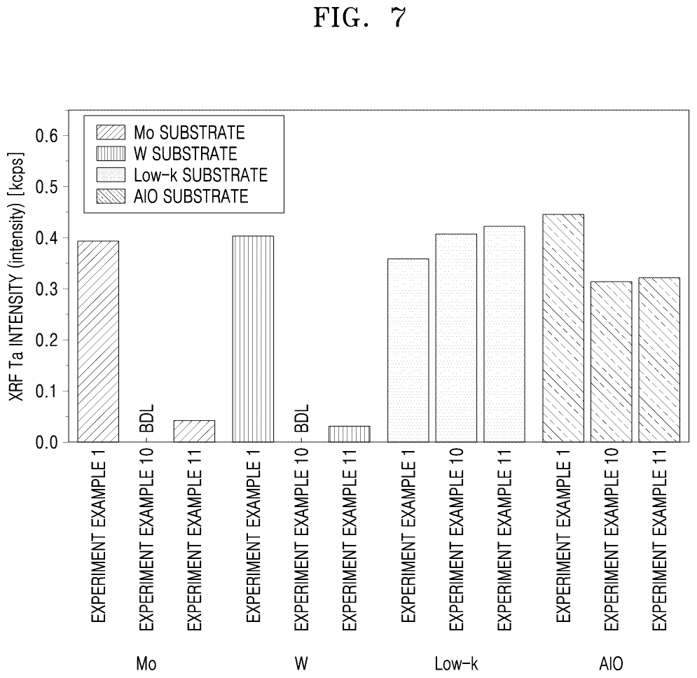

Hereinbelow, an experiment result for selective subsequent film deposition based on ex-situ processing will be described with reference to Table 5 and FIG. 7.

The inhibitor based on vaporization and the fourth substrate obtained by experiment for forming a thin-film formation film are performed under an Ar gas condition with a vacuum break of 2 hours, and then a layer of interest is formed, thereby forming the sixth substrate. For each experiment example, the inhibitory effect of the inhibitor for the Mo substrate, the W substrate, and the Cu substrate under the multi-temperature condition is identified. This result is described with reference to Table 5 and FIG. 7 together.

The ex-situ process and the vacuum break have already been described above.

TABLE 5

| | | | Raw | | | | |
|---|---|---|---|---|---|---|---|
| | | | Material for | | | | |
| | | Raw Material for | Forming | Strength for Forming | | | |
| | | Inhibitor | Thin Film | Thin Film (kcps) | | | |
| | Substrate | Reaction Temperature | | Mo | W | Low-k | AlxOy |
| Experiment | Fifth | — | 250° C. | 0.39 | 0.40 | 0.36 | 0.44 |
| Example 1 | Substrate | | | | | | |
| Experiment | Fourth | 400° C. | 250° C. | BDL | BDL | 0.41 | 0.31 |
| Example 10 | Substrate | | | | | | |
| Experiment | Sixth | 400° C. | 250° C. | 0.04 | 0.03 | 0.42 | 0.32 |
| Example 14 | Substrate | | | | | | |

Referring to Table 5, XRF results of the Ta atom in in-situ and ex-situ are respectively measured as BDL and 0.04 kcps for the Mo substrate and as BDL and 0.03 kcps for the W substrate. Comparing the foregoing XRF results with XRF results of the Ta atom in in-situ and ex-situ being respectively measured as 0.04 kcps and 0.3 kcps for the low-k substrate and the AlO substrate, a selective deposition effect based on the inhibitor is large both in the in-situ process and the ex-situ process.

The inhibitor based on vaporization and the fourth substrate obtained by experiment for forming a thin-film formation film are performed under an Ar gas condition with a vacuum break of 2 hours, and then a layer of interest is formed, thereby forming the seventh substrate. For each experiment example, the inhibitory effect of the inhibitor for the Cu substrate under the multi-temperature condition is identified. This result is described with reference to Table 6 provided below.

TABLE 6

| Inhibitor | | XPS Result Value |
|---|---|---|
| Temperature | Experiment Environment | $Ta ( \frac{XPS [ with inhibitor ]}{XPS [ without inhibitor ]} )$ |
| 400° C. | In-situ | 0.03 |
| 400° C. | Ex-situ | 0.03 |

Referring to Table 6, it may be seen that the fourth substrate exhibits the effect of inhibiting Ta atoms by the inhibitor at 400° C. in both the in-situ environment and the ex-situ environment.

$$Ta ( \frac{XPS [ with inhibitor ]}{XPS [ without inhibitor ]} )$$

may be a value for comparing Ta atom X-ray photoelectron spectroscopy (XPS) result values for application of the inhibitor and non-application of the inhibitor. In both the in-situ environment and the ex-situ environment, the Ta atom XPS result value in the application of the inhibitor is 0.03 times lower than that in the non-application of the inhibitor. That is, in both the in-situ environment and the ex-situ environment, the effect of inhibiting the Ta atoms of the inhibitor is large.

Hereinbelow, a result of calculating energy stabilized as the inhibitor is adsorbed to each substrate using quantum mechanical simulation with respect to binding energy of the Ta atoms is described with reference to Table 7.

TABLE 7

| | | | | | | | | Growth | |
|---|---|---|---|---|---|---|---|---|---|
| | Non-Growth Surfaces | | | | | | | Surfaces | |
| | Metal | | | | | Metal Oxide | | Dielectric | |
| Inhibitor | Mo | W | Ru | Co | Cu | MoOx | CuOx | SiO2 | AlOx |
| 4TBBA | −5.27 | −5.56 | −3.98 | −4.32 | −1.25 | −2.44 | −2.55 | −0.91 | −0.75 |
| Octanal | −3.41 | −3.29 | −2.19 | −1.93 | −1.04 | −2.70 | −2.32 | −0.50 | −0.50 |
| Decanal | −3.60 | −3.68 | −2.47 | −2.14 | −1.27 | −3.08 | −2.33 | −0.54 | −0.60 |
| Dodecanal | −3.88 | −3.76 | −2.67 | −2.75 | −1.47 | −3.45 | −2.34 | −0.64 | −0.64 |

| | |
|---|---|
| Chemical Adsorption (metal-C/O bonds formation) | Physical |
| | Adsorption |

Referring to a simulation result shown in Table 7, by using an inhibitor according to the inventive concept, selective adsorption of not only Mo, W, and Cu, but also Ru, Co, MoOx metal oxide, CuOx metal oxide series may be possible.

As above, embodiments have been disclosed in the drawings and specifications. Although the embodiments have been described using specific terms herein, they are merely used for the purpose of explaining the technical idea of the inventive concept, and are not used to limit the scope of the inventive concept described in the claims. It would be fully understood by those of ordinary skill in the art that various modifications and other equivalent embodiments are possible from the embodiments. Accordingly, the true technical scope of the inventive concept should be defined by the technical spirit of the appended claims.

While the inventive concept has been particularly shown and described with reference to embodiments thereof, it will be understood that various changes in form and details may be made therein without departing from the spirit and scope of the following claims.

What is claimed is:

1. A method for selective deposition of a layer of interest, the method comprising:
providing a first film comprising a first surface and a second film comprising a second surface;
forming an inhibitor layer on the first surface of the first film;
forming a layer of interest surrounding the second surface of the second film; and
exposing the first surface by removing the inhibitor layer,
wherein the second film comprises at least one selected from a low-k material, SiOx, an insulating material, a metal oxide, and a combination thereof,
the inhibitor layer comprises an alkyl aldehyde, and
the first film comprises: at least one selected from W, Mo, Ru, Cu, Co, and a combination thereof; and at least one selected from WOx, MoOx, RuOx, CuOx, CoOx, and a combination thereof.

2. The method of claim 1, wherein the inhibitor layer is chemically-adsorbed only to the first surface and is not adsorbed to the second surface.

3. The method of claim 1, wherein the alkyl aldehyde comprised in the inhibitor layer comprises at least one selected from valeraldehyde, octanal, decanal, dodecanal, and a combination thereof.

4. The method of claim 1, wherein a number of carbon atoms included in the alkyl aldehyde comprised in the inhibitor layer is 1 to 15.

5. The method of claim 1, further comprising, after the forming of the inhibitor layer on the first surface of the first film, performing a vacuum break.

6. The method of claim 1, wherein the layer of interest is not formed on the inhibitor layer.

7. The method of claim 1, wherein the forming of the inhibitor layer and the forming of the layer of interest are performed at a same temperature.

8. The method of claim 1, wherein the forming of the inhibitor layer and the forming of the layer of interest are performed at different temperatures from each other.

9. The method of claim 1, wherein the exposing of the first surface by selectively removing the inhibitor layer comprises exposing all of the first surface.

10. A method for selective deposition of a layer of interest, the method comprising:
providing a first film comprising a first surface and a second film comprising a second surface;
forming an inhibitor layer on the first surface of the first film;
performing a vacuum break on the first film and the second film;
forming a layer of interest surrounding the second surface of the second film; and
exposing the first surface by removing the inhibitor layer,
wherein the second film comprises at least one selected from a low-k material, SiOx, an insulating material, a metal oxide, and a combination thereof,
the inhibitor layer comprises an aryl aldehyde, and
the first film comprises: at least one selected from W, Mo, Ru, Cu, Co, and a combination thereof; and at least one selected from WOx, MoOx, RuOx, CuOx, CoOx, and a combination thereof.

11. The method of claim 10, wherein the inhibitor layer comprises 4-tert-butylbenzaldehyde (4TBBA).

12. The method of claim 10, wherein a number of carbon atoms included in the aryl aldehyde comprised in the inhibitor layer is 6 to 15.

13. The method of claim 10, wherein the inhibitor layer is chemically-adsorbed to the first surface and is not adsorbed to the second surface, and the layer of interest is not formed on the inhibitor layer.

14. The method of claim 10, wherein the forming of the inhibitor layer and the forming of the layer of interest are performed at a same temperature.

15. The method of claim 10, wherein the forming of the inhibitor layer and the forming of the layer of interest are performed at different temperatures from each other.

16. The method of claim 10, wherein the exposing of the first surface by removing the inhibitor layer comprises exposing all of the first surface.

17. A method for selective deposition of a layer of interest, the method comprising:
providing a first film comprising a first surface and a second film comprising a second surface;
forming an inhibitor layer on the first surface of the first film;
forming a layer of interest surrounding the second surface of the second film; and
exposing the first surface by removing the inhibitor layer,
wherein the inhibitor layer comprises an aldehyde represented by: 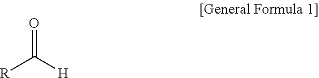
wherein,
R indicates an alkyl group, an alkoxy group, an amine group, a methoxy group, an amide group, or an ester group,
the first film comprises: at least one selected from W, Mo, Ru, Cu, Co, and a combination thereof; and at least one selected from WOx, MoOx, RuOx, CuOx, CoOx, and a combination thereof, and
the second film comprises at least one selected from a low-k material, SiOx, an insulating material, a metal oxide, and a combination thereof.

18. The method of claim 17, wherein a number of carbon atoms included in the R group of the aldehyde comprised in the inhibitor layer is 1 to 15.

19. The method of claim 17, further comprising, after the forming of the inhibitor layer having a conformal thickness on the first surface of the first film, performing a vacuum break.

20. The method of claim 17, wherein the forming of the inhibitor layer is performed within a range of about room temperature (25° C.) to about 700° C.
